(19) United States
(12) Patent Application Publication
(10) Pub. No.: US 2008/0038462 A1
(43) Pub. Date: Feb. 14, 2008

(54) Method of forming a carbon layer on a substrate

(75) Inventors: Mirko Vogt, Dresden (DE); Hans-Peter Sperlich, Dresden (DE); Sven Frauenstein, Dresden (DE); Andre Neubauer, Dresden (DE)

Correspondence Address: PATTERSON & SHERIDAN, LLP;Gero McClellan / Qimonda, 3040 POST OAK BLVD.,, SUITE 1500, HOUSTON, TX, 77056, US

(73) Assignee: Qimonda AG, Munchen (DE)

(21) Appl. No.: 11/501,244

(22) Filed: Aug. 9, 2006

(51) Int. Cl. C23C 16/00; H05H 1/24

(52) U.S. Cl. 427/249.1; 427/569

(57) ABSTRACT

The present invention relates to a method of forming a carbon layer on a substrate. A substrate with a structured surface is provided, the structured surface comprising a sidewall. A plasma is formed from an atmosphere comprising a gaseous hydrocarbon compound. The substrate is processed with the plasma, thereby depositing a carbon layer on the structured surface of the substrate. According to one aspect of the invention, the gaseous hydrocarbon compound comprises a ratio of less than 2:1 between hydrogen and carbon. According to another aspect of the invention, the atmosphere comprises a gaseous additive compound, the gaseous additive compound having an affinity for binding to hydrogen. Accordingly, the plasma comprises a reduced reactive hydrogen content, thus enabling an improved carbon deposition at the sidewall of the structured surface.

### BACKGROUND OF THE INVENTION

1. Field of the Invention

The present invention generally relates to a method of forming a carbon layer on a substrate. More particularly, the invention relates to a method of forming a carbon layer on a structured surface of a substrate, wherein the structured surface comprises a sidewall.

2. Description of the Related Art

The fabrication of highly integrated electrical circuits (ICs) with small structural dimensions is carried out with the aid of lithographic structuring techniques. These techniques generally comprise the steps of depositing a film or layer on a semiconductor substrate, forming a mask on the layer, the mask having a mask structure, and subsequently transferring the mask structure into the layer by performing e.g. an etch process or an ion implantation doping process. This procedure is repeated a number of times with varying masks in order to fabricate integrated circuits on the substrate.

Forming a mask generally comprises depositing a thin layer of a radiation sensitive photoresist on the layer to be structured and exposing the same by radiation transmitted through a lithographic reticle. In the so-called photolithography, electromagnetic radiation is used. During the exposing step, a lithographic structure located on the reticle is imaged on the photoresist layer. This structure is transferred into the photoresist layer by performing a development process. The thus structured photoresist layer serves as a mask for patterning the underlying layer.

In the case of an etch process or an ion implantation doping process, typically a so-called hard mask is applied. Structuring a layer thereby comprises the steps of depositing a hard mask layer on the layer to be structured, forming a resist mask having a desired structure on the hard mask layer according to the process steps described above and transferring the resist structure into the hard mask layer by means of an etch process. The thus provided hard mask is used to structure the underlying layer.

Common materials for hard masks applied in semiconductor production are e.g. silicon oxide, silicon nitride, silicon oxynitride and polysilicon. In addition new hard mask concepts based on alternative materials are pursued. A relatively new application in semiconductor processing is the use of carbon as a hard mask material. As an example U.S. 2004/0023502 A1 discloses a carbon hard mask used in an etch process for patterning a metal layer. At this, the preceding deposition of carbon on the metal layer is carried out by means of a chemical vapor deposition (CVD) using hydrocarbon precursors.

Due to a bad etch selectivity between photoresists and carbon, forming a carbon hard mask starting from an unstructured carbon layer typically comprises depositing a thin cap layer, in particular a silicon based cap layer consisting of e.g. silicon oxynitride or silicon oxide on top of the carbon layer, structuring the cap layer with the aid of a lithographic process using a photoresist, and subsequently patterning the carbon layer with the aid of the structured cap layer. Furthermore, the (unstructured) cap layer prevents an unwanted etching of carbon in the course of a lithography rework process, i.e. photoresist removal by applying e.g. an oxygen etch plasma in case of a faulty lithographic process, e.g. due to a CD (critical dimension) specification violation. The cap layer usually has a thickness in the range of about 20 nm to 60 nm.

A conventional carbon deposition process carried out for providing a carbon layer is a plasma enhanced chemical vapor deposition (PECVD) using propylene (C₃H₆) as a carbon containing precursor. A disadvantage of this process is a low deposition rate on vertical or inclined sidewalls of a structured substrate surface. Moreover, the deposited carbon layer comprises a rough and undefined surface at such structures.

As a consequence, the subsequently deposited cap layer does not completely cover the carbon layer. Accordingly, there arises the danger of an unwanted carbon removal or attack in a lithography rework process as well as in an etch process carried out for structuring the carbon layer. In either case the carbon layer does no longer sufficiently protect the underlying layer. Moreover, a defective carbon deposition also affects further non-planar applications which require a defined carbon deposition on sidewalls of structures wherein carbon acts e.g. as a hard mask or a remaining insulating film.

For way of illustration, the following FIGS. 1 to 4 show cross sections of structured substrate surfaces comprising a carbon layer formed thereon. The depicted cross sections are based on images taken by a scanning electron microscope (SEM). In each case, the carbon deposition was carried out with the aid of the above mentioned conventional PECVD process using propylene.

FIG. 1 depicts a surface of a substrate comprising a structured layer 102 containing borosphosphosilicate glass (BPSG) which is located on an underlayer 105. A trench 108 divides the structured layer 102 into two sections having inclined sidewalls 103, in this way providing a tapered lithography mark. A carbon layer 101 is deposited on the structured layer 102 and on the exposed section of the underlayer 105. In the area of the sidewalls 103, the carbon layer 101 has a rough and undefined surface and, in comparison to the horizontal sections of the layers 102, 105, a reduced thickness. The carbon deposition at the sidewalls 103 can be characterized as “columnar growth”.

FIG. 2 shows another example of a lithography mark formed in the surface of a substrate. A structured BPSG layer 112 comprising an essentially vertical sidewall 113 is located on an underlayer 115. A carbon layer 111 and a cap layer 116 are deposited on the layers 112, 115. An undefined sidewall coverage and a reduced thickness of the carbon layer 112 in the area of the sidewall 113 can clearly be seen from FIG. 2.

FIG. 3 depicts a structured surface of a substrate after a lithography rework process comprising a metal layer 122 located on a structured underlayer 125, the metal layer 122 comprising inclined sidewalls 123. A carbon layer 121 and a cap layer 126 are deposited on top of the metal layer 122 for masking purposes. The carbon layer 121 comprises a defect 124 in form of a void at a sidewall 123. This defect 124 is due to an imperfect carbon deposition at the sidewall 123 and therefore an incomplete coverage of the subsequently deposited cap layer 126 on the carbon layer 121, thus resulting in a carbon attack in the course of the following lithography rework process.

FIG. 4 shows another example of a structure comprising a structured layer 132 having rounded or essentially inclined sidewalls 133 and a carbon layer 131 deposited thereon. A cap layer 136 and an additional cover layer 137 are formed on top of the carbon layer 131. The carbon layer 131 comprises defects 134 or voids at the sidewalls 131. These defects 134 are again due to a defective carbon deposition at the sidewalls 133 and therefore only a partial coverage of the cap layer 136 on the carbon layer 131, in this way resulting in a carbon removal in the course of a lithography rework process.

In order to improve the step coverage of a carbon PECVD layer on a structured surface of a substrate, the performance of liquid hydrocarbon precursors is being evaluated. However, the application of liquid precursors requires the installation of liquid supply systems and evaporation devices to the existing CVD tools, and is therefore complex and cost intensive.

### SUMMARY OF THE INVENTION

Various aspects of the present invention provide an improved method of forming a carbon layer on a structured surface of a substrate.

For one embodiment of the present invention, a method of forming a carbon layer on a substrate is provided which comprises the steps of providing a substrate with a structured surface, wherein the structured surface comprises a sidewall; forming a plasma from an atmosphere comprising a gaseous hydrocarbon compound, wherein the gaseous hydrocarbon compound comprises a ratio of less than 2:1 between hydrogen and carbon; and processing the substrate with the plasma, thereby depositing a carbon layer on the structured surface of the substrate.

For another embodiment of the present invention, a method of forming a carbon layer on a substrate is provided which comprises the steps of providing a substrate with a structured surface, wherein the structured surface comprises a sidewall; forming a plasma from an atmosphere comprising a gaseous hydrocarbon compound and a gaseous additive compound, wherein the gaseous additive compound has an affinity for binding to hydrogen; and processing the substrate with the plasma, thereby depositing a carbon layer on the structured surface of the substrate.

For another embodiment of the present invention, a method of forming a carbon layer on a substrate is provided which comprises the steps of providing a substrate with a structured surface, wherein the structured surface comprises a sidewall; forming a plasma from an atmosphere comprising a gaseous hydrocarbon compound and a gaseous additive compound, wherein the gaseous hydrocarbon compound comprises a ratio of less than 2:1 between hydrogen and carbon and wherein the gaseous additive compound has an affinity for binding to hydrogen; and processing the substrate with the plasma, thereby depositing a carbon layer on the structured surface of the substrate.

### BRIEF DESCRIPTION OF THE DRAWINGS

These and other features of the present invention will become clear from the following description taken in conjunction with the accompanying drawings. It is to be noted, however, that the accompanying drawings illustrate only typical embodiments of the present invention and are, therefore not to be considered limiting of the scope of the invention. The present invention may admit other equally effective embodiments.

FIGS. 1 to 4 illustrate cross sections of structured substrate surfaces comprising a carbon layer formed thereon, wherein carbon deposition was carried out according to a conventional method;

FIG. 5 illustrates a flow diagram of a method of forming a carbon layer on a substrate according to one embodiment of the present invention;

FIG. 6 illustrates a schematic view of a PECVD device for carrying out a carbon deposition;

FIGS. 7 and 8 illustrate cross sections of structured substrate surfaces comprising a carbon layer formed thereon, wherein carbon deposition was carried out by means of a method according to an embodiment of the present invention;

FIG. 9 illustrates a flow diagram of a method of forming a carbon layer on a substrate according to another embodiment of the present invention; and

FIG. 10 illustrates a flow diagram of a method of forming a carbon layer on a substrate according to a further embodiment of the present invention.

### DETAILED DESCRIPTION OF PREFERRED EMBODIMENTS

The present invention provides an improved method of forming a carbon layer on a substrate by means of a PECVD process. In particular, according to the invention an enhanced step coverage of the carbon layer at sidewalls of a structured surface of the substrate is provided.

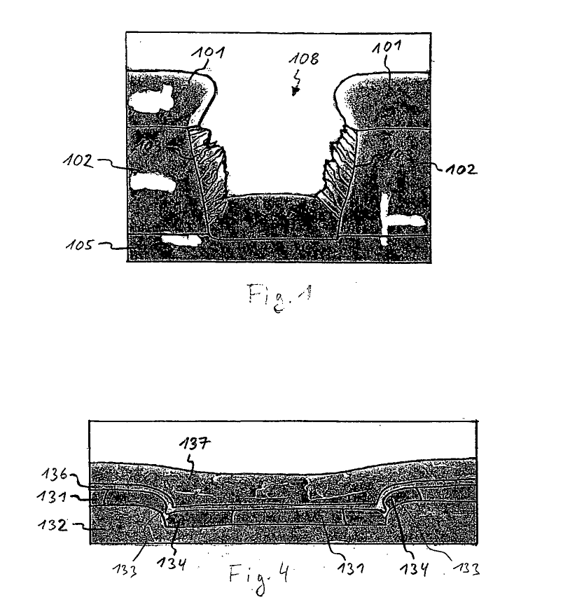

At this, the structured surface of the substrate can be constituted by various arrangements of structured and unstructured layers, respectively. Examples of such layer arrangements can be derived from FIGS. 1 to 4 and 7, 8. A structured substrate surface can e.g. be formed by the application of conventional deposition and structuring methods, which are well known by those skilled in the art.

In a PECVD process, the substrate is exposed to an atmosphere comprising gaseous precursors for the layer constituents. By applying an electromagnetic power like e.g. an RF power (radio frequency) a plasma is generated. The plasma comprises chemically reactive precursor compounds and/or radicals which diffuse to and are adsorbed at the surface of the substrate where they react to form the deposited layer. For forming a carbon layer, hydrocarbon precursors are being used.

Embodiments of the present invention are based on the experience of the inventors that by reducing the reactive hydrogen content in the plasma, the carbon deposition is being improved, in particular at sidewalls of a structured surface of a substrate.

On the one hand, the mechanism of improving the carbon deposition by reducing the hydrogen content in the plasma can be explained by anisotropic film properties of PECVD carbon. If a structured substrate with a PECVD carbon layer on top of the substrate surface is exposed to a hydrogen plasma for carrying out an etch process, the carbon etch rate is significantly higher in the direction parallel to a horizontal plane of the substrate surface (lateral or horizontal etch component) compared to the perpendicular direction (vertical etch component). In a PECVD process using a hydrocarbon precursor, reactive hydrogen is dissociated from precursor compounds within the plasma, thereby etching the carbon (essentially) laterally and simultaneously to the carbon deposition. With regard to the above mentioned conventional PECVD process using a hydrocarbon precursor with a relatively high fraction of hydrogen, thus resulting in a relatively high hydrogen content in the plasma, the consequence is a low carbon deposition and especially a rough carbon surface at sidewalls of the structured substrate surface. Accordingly, by reducing the hydrogen content in the plasma, an enhanced carbon deposition is made possible.

On the other hand, reducing the reactive hydrogen content in the plasma can have a positive influence on the adhesion of chemically reactive precursor compounds adsorbed at a surface, also referred to as sticking coefficient. Due to the hydrogen content in the plasma, hydrogen bonds are formed at the surface, in this way hindering the adhesion of radicals and precursor compounds required for the layer deposition. These “blocking” hydrogen bonds can however be broken by ions emitted from the plasma, wherein this effect has a strong impact only on a planar or horizontal surface section. By reducing the hydrogen content in the plasma, the formation of hydrogen bonds at the substrate surface is reduced. Therefore the sticking coefficient and thus the carbon deposition rate is particularly increased at a sidewall of the structured surface at which breaking of hydrogen bonds by ions plays an inferior role.

FIG. 5 shows a flow diagram of a method of forming a carbon layer on a substrate according to one embodiment of the present invention. In a first step 31, a substrate 17, in particular a semiconductor substrate 17 with a structured surface is provided. The structured surface comprises at least one sidewall, which is oriented e.g. vertically or inclined with respect to a horizontal plane of the structured surface. The structured surface is e.g. constituted by an arrangement of layers and underlayers or a layer system.

In a step 32, a plasma 18 is formed from an atmosphere comprising a gaseous hydrocarbon precursor. According to the invention, the hydrocarbon precursor comprises an atomic ratio of less than 2:1 between hydrogen and carbon. In comparison to the above described conventional PECVD process using propylene (C₃H₆) as a carbon containing precursor, the provided plasma 18 consequently has a reduced hydrogen content. Preferably, the hydrocarbon precursor is a gas at standard ambient temperature and pressure.

In a step 33, the substrate 17 is processed with the provided plasma 18. In this way a carbon layer, in particular an amorphous carbon layer is deposited on the structured surface of the substrate 17.

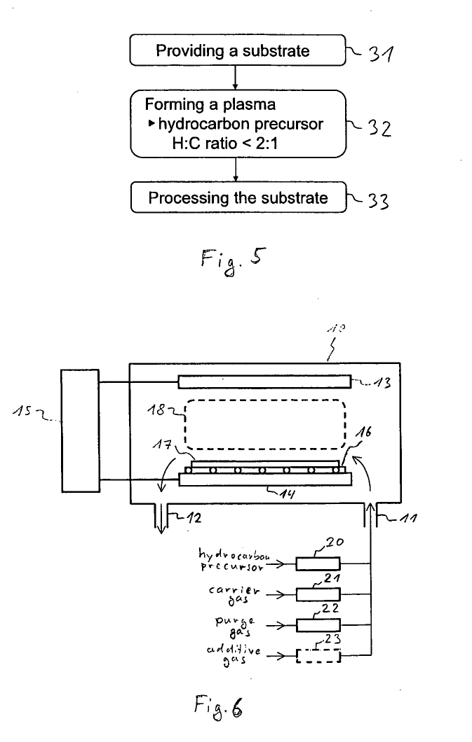

For carrying out process steps 32, 33 of the method depicted in FIG. 5, a single wafer PECVD tool as schematically illustrated in FIG. 6 can be used. The PECVD tool comprises a process chamber 10 with a gas inlet 11 and a gas outlet 12. The gas outlet 12 is connected to a vacuum pump (not shown) for establishing a process pressure, typically in the range of 3 Torr to 8 Torr, preferably 5 Torr to 6 Torr, in the process chamber 10.

The process chamber 10 comprises a heater 16 for providing a process temperature, which is typically in the range of 300° C. to 500° C. The process chamber 10 is further provided with electrodes 13, 14 for capacitively applying an electromagnetic power. For this, the electrodes 13, 14 are connected to a RF power source 15.

Flow controllers 20, 21, 22 are provided for the introduction of the necessary gases into the process chamber 10. The flow controllers 20, 21, 22 are e.g. connected to gas containers (not shown). Flow controller 20 introduces a hydrocarbon precursor gas and flow controller 21 introduces an inert carrier gas like e.g. helium into the process chamber 10. Flow controller 22 introduces a purge gas used for cleaning the process chamber 10 after a deposition process.

Prior to the actual carbon deposition process, the substrate 17 is introduced into the process chamber 10 and positioned on the heater 16 in order to provide the usual process temperature. The flow controllers 20, 21 are activated to permit the required flow rates of the hydrocarbon precursor gas and the carrier gas to enter the process chamber 10. Consequently an atmosphere comprising a gaseous hydrocarbon compound is provided in the process chamber 10, wherein the process pressure is set with the aid of the vacuum pump (not shown). The electrodes 13, 14 are activated with the aid of the RF power source 15 to provide a required power density, thereby striking a plasma 18 in the process chamber 10. In this way the substrate 17 is processed with the plasma 18, wherein deposition of a carbon layer on the substrate surface takes place.

Due to the reduced hydrogen content in the plasma 18, the method depicted in FIG. 5 makes possible an improved carbon deposition on the structured surface of the substrate 17, in particular at sidewalls of the structured substrate surface. An enhanced carbon deposition is particularly achieved by applying a hydrocarbon precursor which comprises an atomic ratio of 1:1 between hydrogen and carbon. A gaseous precursor having such an atomic ratio between hydrogen and carbon and which is therefore preferably applied in the method illustrated in FIG. 5 is acetylene (C₂H₂).

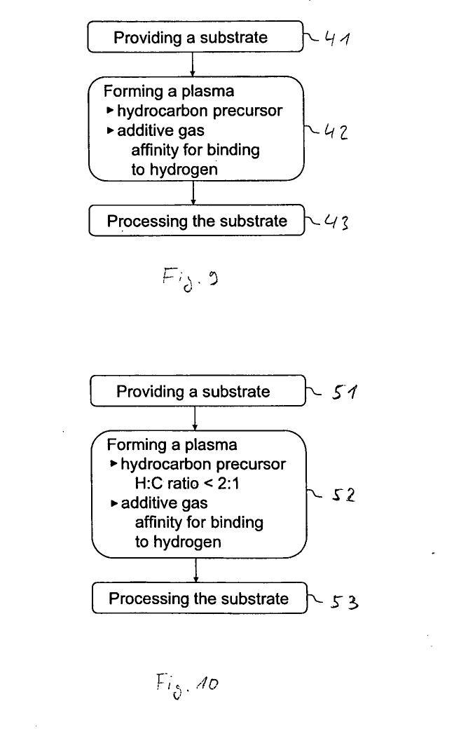

For way of illustration, the following FIGS. 7, 8 show cross sections of structured substrate surfaces comprising a carbon layer deposited thereon, wherein the carbon deposition was carried out according to the method depicted in FIG. 5 using acetylene as hydrocarbon precursor. The depicted cross sections are again based on images taken by a scanning electron microscope.

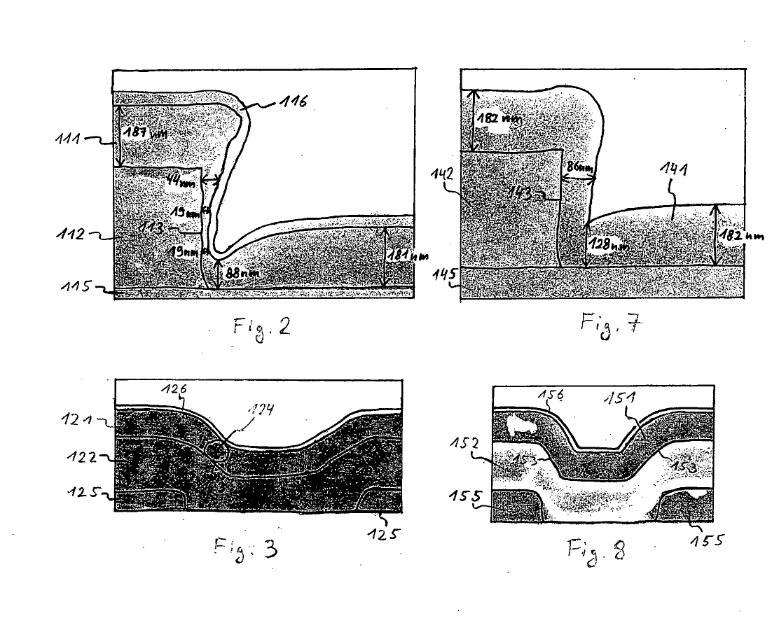

The structure depicted in FIG. 7 comprises a structured layer 142 with an essentially vertical sidewall 143, which is located on an underlayer 145. A carbon layer 141 is deposited on the structured layer 142 and the underlayer 145. Unlike the structure depicted in FIG. 2, a defined, homogeneous step coverage of the carbon layer 141 is achieved. Moreover, the carbon layer 141 has an increased thickness at the sidewall 143, which is about 50% of the thickness of the carbon layer 141 at the horizontal sections of the layers 142, 145.

FIG. 8 shows a structured substrate surface comparable to the substrate surface depicted in FIG. 3, again after a lithography rework process. A metal layer 152 is located on a structured underlayer 155, the metal layer 152 comprising inclined sidewalls 153. A carbon layer 151 and a cap layer 156 are deposited on top of the metal layer 152 for masking purposes. Unlike the carbon layer 121 depicted in FIG. 3, the carbon layer 151 depicted in FIG. 5 comprises no defects at sidewalls 153 of the metal layer 152. This is due to a defined, homogenous carbon deposition at the sidewalls 153 and therefore a complete coverage of the cap layer 156 on the carbon layer 151, consequently providing a safe and reliable protection of the carbon layer 151 against a carbon attack in the course of the lithography rework process.

FIG. 9 shows a flow diagram of a method of forming a carbon layer on a substrate according to another embodiment of the present invention. In a first step 41, a substrate 17 with a structured surface is provided. Again, the structured surface comprises at least one sidewall, which is oriented e.g. vertically or inclined with respect to a horizontal plane of the structured surface. In a step 42, a plasma 18 is formed from an atmosphere comprising a gaseous hydrocarbon precursor and an additive gas, wherein the additive gas has an affinity for binding to hydrogen. In this way a reduction of the reactive hydrogen content in the plasma 18 can also be achieved, e.g. by the formation of chemically inactive compounds between hydrogen and constituents of the additive gas. The substrate 17 is processed with the plasma 18 in a step 43, thereby depositing a carbon layer on the structured surface of the substrate 17. Due to the reduced hydrogen content in the plasma 18, the carbon deposition is characterized by an improved step coverage.

For carrying out process steps 42, 43 of the method depicted in FIG. 9, again the PECVD tool illustrated in FIG. 6 can be used. For this, an additional flow controller 23 is provided for the introduction of the additive gas into the process chamber 10. In order to achieve advantageous deposition results, the deposition is preferably carried out with a volume ratio of the additive gas to the gaseous hydrocarbon precursor ranging from 10% to 20%. The volume ratio is set with the aid of the flow controllers 20, 23.

The additive gas preferably comprises an oxygen containing compound. In particular, this includes a gas from the group consisting of O₂, N₂O and CO₂.

Alternatively, the additive gas preferably comprises a fluorine containing compound. In particular, this includes a fluorinated carbon gas, preferably a gas from the group consisting of C₄F₈, C₄F₆ and C₃F₈. By applying a fluorine containing additive gas, not only a reduction of the reactive hydrogen content in the plasma is achieved but also the deposition of fluorinated amorphous carbon. The thus provided fluorinated carbon layer features e.g. an enhanced chemical resistance.

Furthermore, the additive gas having an affinity for binding to hydrogen can comprise a mixture of different gases. In particular, the additive gas preferably comprises an oxygen containing compound and a fluorine containing compound.

FIG. 10 shows a flow diagram of a method of forming a carbon layer on a substrate according to a further embodiment of the present invention, which is a combination of the methods depicted in FIGS. 5 and 9. In a first step 51, a substrate 17 with a structured surface is provided. Again, the structured surface comprises at least one sidewall, which is arranged e.g. vertically or inclined with respect to a horizontal plane of the structured surface. In a step 52, a plasma 18 is formed from an atmosphere comprising a gaseous hydrocarbon precursor and an additive gas, wherein the hydrocarbon precursor comprises an atomic ratio of less than 2:1 between hydrogen and carbon and wherein the additive gas has an affinity for binding to hydrogen. Consequently, the plasma 18 comprises a reduced hydrogen content. The substrate 17 is processed with the plasma 18 in a step 53, thereby depositing a carbon layer on the structured substrate surface. The two process steps 52, 53 can also be carried out with the aid of the PECVD tool illustrated in FIG. 6. Again, due to the reduced hydrogen content in the plasma 18, the carbon deposition is characterized by an improved step coverage.

Embodiments of the inventive method can be applied for the improved carbon deposition on a structured surface of a substrate, the structured surface comprising at least one sidewall which is arranged basically orthogonal to a planar or horizontal plane of the structured surface (cp. FIG. 7). At this, a basically orthogonal arrangement includes a sidewall angle relative to the horizontal plane of the structured surface in the range of 80° to 90°, which can e.g. be due to the way of manufacturing.

Moreover, embodiments of the inventive method can be applied for the improved carbon deposition on a structured surface of a substrate comprising at least one inclined sidewall (cp. FIG. 8). At this, the sidewall can have a sidewall angle relative to a horizontal plane of the structured surface in the range of 35° to 70°, particularly in the range of 40° to 50°.

While the present invention has been described in terms of specific embodiments, it is evident in view of the foregoing description that various variations and modifications may be carried out without departing from the scope of the invention.

As an example, the steps of forming a plasma and processing a substrate with the plasma can be carried out in PECVD tool having a construction unlike the PECVD tool depicted in FIG. 6. A PECVD tool can alternatively comprise e.g. a twin- or multiple-wafer chamber in order to process two or multiple substrates at the same time. Instead of generating a plasma using capacitively coupled RF power, also inductively coupled RF power can be applied. Moreover, instead of forming a plasma and processing the substrate within the same process chamber, embodiments of a PECVD tool can also be applied at which a plasma is formed in a separate chamber and injected into a process chamber for processing a substrate which is introduced therein.

Furthermore, embodiments of the present invention can be applied for the enhanced deposition of carbon on structured substrate surfaces having sidewalls of either form. This includes not only basically vertical and inclined or oblique sidewalls but also sidewalls having a different shape, e.g. a rounded shape.

A carbon layer formed on a substrate with the aid of an embodiment of the invention can be applied to further processing. This includes e.g. a structuring process with the aid of a cap layer for providing a carbon hard mask. The thus provided carbon hard mask (and also the preceding unstructured carbon layer) features a reliable protection of an underlying layer.

What is claimed is:

1. A method of forming a carbon layer on a substrate, comprising:
providing a substrate with a structured surface, wherein the structured surface comprises a sidewall;
forming a plasma from an atmosphere comprising a gaseous hydrocarbon compound, wherein the gaseous hydrocarbon compound comprises a ratio of less than 2:1 between hydrogen and carbon; and
processing the substrate with the plasma, thereby depositing a carbon layer on the structured surface of the substrate.

2. The method according to claim 1, wherein the gaseous hydrocarbon compound comprises a ratio of 1:1 between hydrogen and carbon.

3. The method according to claim 1, wherein the gaseous hydrocarbon compound is C₂H₂.

4. The method according to claim 1, wherein the sidewall has a sidewall angle relative to a horizontal plane of the structured surface in the range of 35° to 70°.

5. The method according to claim 1, wherein the sidewall has a sidewall angle relative to a horizontal plane of the structured surface in the range of 40° to 50°.

6. the method according to claim 1, wherein the sidewall has a sidewall angle relative to a horizontal plane of the structured surface in the range of 80° to 90°.

7. A method of forming a carbon layer on a substrate, comprising:
providing a substrate with a structured surface, wherein the structured surface comprises a sidewall;
forming a plasma from an atmosphere comprising a gaseous hydrocarbon compound and a gaseous additive compound, wherein the gaseous additive compound has an affinity for binding to hydrogen; and
processing the substrate with the plasma, thereby depositing a carbon layer on the structured surface of the substrate.

8. The method according to claim 7, wherein the gaseous additive compound comprises an oxygen containing compound.

9. The method according to claim 7, wherein the gaseous additive compound is from the group consisting of O₂, N₂O and CO₂.

10. The method according to claim 7, wherein the gaseous additive compound comprises a fluorine containing compound.

11. The method according to claim 7, wherein the gaseous additive compound is a fluorinated carbon gas.

12. The method according to claim 7, wherein the gaseous additive compound is from the group consisting of C₄F₈, C₄F₆ and C₃F₈.

13. The method according to claim 7, wherein the gaseous additive compound comprises an oxygen containing compound and a fluorine containing compound.

14. The method according to claim 7, wherein a volume ratio of the gaseous additive compound to the gaseous hydrocarbon compound ranges from 10% to 20%.

15. The method according to claim 7, wherein the sidewall has a sidewall angle relative to a horizontal plane of the structured surface in the range of 35° to 70°.

16. The method according to claim 7, wherein the sidewall has a sidewall angle relative to a horizontal plane of the structured surface in the range of 40° to 50°.

17. The method according to claim 7, wherein the sidewall has a sidewall angle relative to a horizontal plane of the structured surface in the range of 80° to 90°.

18. A method of forming a carbon layer on a substrate, comprising:
providing a substrate with a structured surface, wherein the structured surface comprises a sidewall;
forming a plasma from an atmosphere comprising a gaseous hydrocarbon compound and a gaseous additive compound, wherein the gaseous hydrocarbon compound comprises a ratio of less than 2:1 between hydrogen and carbon and wherein the gaseous additive compound has an affinity for binding to hydrogen; and
processing the substrate with the plasma, thereby depositing a carbon layer on the structured surface of the substrate.
